(19) United States
(12) Patent Application Publication
(10) Pub. No.: US 2022/0388112 A1
(43) Pub. Date: Dec. 8, 2022

(54) USING LIGHT COUPLING PROPERTIES FOR MACHINE-LEARNING-BASED FILM DETECTION

(71) Applicant: Applied Materials, Inc., Santa Clara, CA (US)

(72) Inventors: Nojan Motamedi, Sunnyvale, CA (US); Dominic J. Benvegnu, La Honda, CA (US); Boguslaw A. Swedek, Morgan Hill, CA (US)

(73) Assignee: Applied Materials, Inc., Santa Clara, CA (US)

(21) Appl. No.: 17/825,839

(22) Filed: May 26, 2022

Related U.S. Application Data
(63) Continuation-in-part of application No. 17/338,032, filed on Jun. 3, 2021.

(51) Int. Cl. B24B 37/013; G01B 11/06; H01L 21/66

(52) U.S. Cl. CPC B24B 37/013; G01B 11/0625; H01L 22/26

(57) ABSTRACT

Exemplary semiconductor processing systems may include a substrate support defining an aperture therethrough. The processing systems may include a light assembly having a light source that emits an optical signal that is directed toward the aperture. The optical signal may have a high angle of incidence relative to the substrate support. The processing systems may include a photodetector aligned with an angle of reflectance of the optical signal. A controller for the processing system may be programmed to receive an amount of the optical signal received by the photodetector and determine a thickness of the outermost layer of film. The controller may include a model trained to classify based on the optical signal. The output of the model may be used to control a process performed on the substrate.

### CROSS-REFERENCES TO RELATED APPLICATIONS

This application is a continuation-in-part of U.S. patent application Ser. No. 17/338,032 filed on Jun. 3, 2021, and entitled “USING LIGHT COUPLING PROPERTIES FOR FILM DETECTION,” which is incorporated herein by reference.

### TECHNICAL FIELD

The present technology relates to semiconductor systems, processes, and equipment. More specifically, the present technology relates to using optical signals to measure film thickness on a substrate.

### BACKGROUND

An integrated circuit is typically formed on a substrate by the sequential deposition of conductive, semiconductive, and/or insulative layers on a silicon wafer. A variety of fabrication processes use the planarization of a layer on the substrate between processing steps. For example, for certain applications, e.g., polishing of a metal layer to form vias, plugs, and/or lines in the trenches of a patterned layer, an overlying layer is planarized until the top surface of a patterned layer is exposed. In other applications, e.g., planarization of a dielectric layer for photolithography, an overlying layer is polished until a desired thickness remains over the underlying layer.

Chemical mechanical polishing (CMP) is one common method of planarization. This planarization method typically requires that the substrate be mounted on a carrier or polishing head. The exposed surface of the substrate is typically placed against a rotating polishing pad. The carrier head provides a controllable load on the substrate to push it against the polishing pad. Abrasive polishing slurry is typically supplied to the surface of the polishing pad.

One problem in CMP is determining whether the polishing process is complete, i.e., whether a substrate layer has been planarized to a desired flatness or thickness, or when a desired amount of material has been removed. Variations in the slurry distribution, the polishing pad condition, the relative speed between the polishing pad and the substrate, and/or the load on the substrate can cause variations in the material removal rate. These variations, as well as variations in the initial thickness of the substrate layer, cause variations in the time needed to reach the polishing endpoint. Therefore, determining the polishing endpoint merely as a function of polishing time can lead to within-wafer non-uniformity (WIWNU) and wafer-to-wafer non-uniformity (WTWNU).

In some systems, a substrate is optically monitored in-situ during polishing, e.g., through a window in the polishing pad. However, existing optical monitoring techniques may not satisfy increasing demands of semiconductor device manufacturers.

### SUMMARY

Exemplary semiconductor processing systems may include a substrate support defining an aperture therethrough. The processing systems may include a light assembly having a light source that emits an optical signal that is directed toward the aperture. The optical signal may have a high angle of incidence relative to the substrate support. The processing systems may include a photodetector aligned with an angle of reflectance of the optical signal.

In some embodiments, processing systems may include a high refractive index fluid positioned within the aperture. The high refractive index fluid may have a refractive index that is sufficiently high that a magnitude of a tangential wave vector of the optical signal is greater than a magnitude of a wavenumber of a top film of a substrate being processed. The processing systems may include a platen positioned below the substrate support. The platen may define a channel that optically couples the light assembly, the aperture, and the photodetector. A first end of the channel may be sealed by a first quartz window positioned between the first end of the channel and the light assembly. A second end of the channel may be sealed by a second quartz window positioned between the second end of the channel and the photodetector. The light source may include a collimated light source. The collimated light source may include a laser. The light assembly may include at least one mirror that directs light from the light source to the aperture. The processing system may include a controller that includes one or more processors and one or more memory devices storing instructions that, when executed by the one or more processors, cause the one or more processors to perform operations including detecting an amount of the optical signal that is received by the photodetector, and determining a thickness of an outermost layer of film on a substrate based at least in part on the amount of the optical signal that is received by the photodetector. The controller may include a model that is trained to receive the amount of the optical signal that is received by the photodetector and output an indication of the thickness of an outermost layer of the film on the substrate. The model may include a neural network that is trained to classify a location on the substrate as having the outermost layer of the film removed, having a thin layer of the film, or having a thick layer of the film. The operations may further include controlling a polishing process performed on the substrate using the indication of the thickness of the outermost layer of the film on the substrate output by the model. The model may receive the amount of the optical signal that is received by the photodetector as a real-time stream of measurement data received during a polishing process performed on the substrate.

Some embodiments of the present technology may encompass methods of determining a thickness of a film of a semiconductor substrate. The methods may include directing an optical signal to a semiconductor substrate that is positioned on a substrate support. The methods may include receiving a reflected portion of the optical signal from the semiconductor substrate using a photodetector. The methods may include determining an amount of the optical signal that was received by the photodetector in the form of the reflected portion. The methods may include determining a thickness of an outermost layer of film of the semiconductor substrate based at least in part on the amount of the optical signal that was received by the photodetector in the form of the reflected portion.

In some embodiments, a lower magnitude of the reflected portion may correspond with the outermost layer of film having a lower thickness. The methods may include moving the semiconductor substrate relative to the substrate support. The methods may include determining a film thickness at an additional portion of the semiconductor substrate. The methods may include providing a high refractive index fluid on the outermost layer of film of the semiconductor substrate. Providing the high refractive index fluid may include pumping the high refractive index fluid onto the outermost layer of film. The methods may include polishing the semiconductor substrate. The methods may include stopping the polishing upon determining that the thickness of an outermost layer of film of the semiconductor substrate has reached a predetermined threshold. The method may also include providing the amount of the optical signal that was received by the photodetector in the form of the reflected portion to a model trained to classify the thickness of substrate films, and receiving an output from the model comprising an indication of the thickness of the outermost layer of the film on the substrate.

Some embodiments of the present technology may encompass methods of determining a thickness of a film of a semiconductor substrate. The methods may include directing an optical signal to an outermost layer of film on a semiconductor substrate at a high angle of incidence. The outermost layer of film may be covered by a high refractive index fluid. The methods may include receiving a reflected portion of the optical signal from the semiconductor substrate using a photodetector. The methods may include determining an amount of the optical signal that was received by the photodetector in the form of the reflected portion. The methods may include determining a thickness of the outermost layer of film of the semiconductor substrate based at least in part on the amount of the optical signal that was received by the photodetector in the form of the reflected portion.

In some embodiments, a method of determining a thickness of a film of a semiconductor substrate may include directing an optical signal to a semiconductor substrate that is positioned on a substrate support; receiving a reflected portion of the optical signal from the semiconductor substrate using a photodetector; providing an input based on the reflected portion of the optical signal to a model that is trained to classify a thickness of an outermost layer of film on the semiconductor substrate; and determining a thickness of the outermost layer of film of the semiconductor substrate based at least in part on an output from the model.

The model may include a neural network that is trained to classify a location on the semiconductor substrate as having the outermost layer of the film removed, having a thin layer of the film, or having a thick layer of the film. The method may also include controlling a polishing process performed on the substrate using the thickness of the outermost layer of the film on the substrate output by the model. The model may receive the reflected portion of the optical signal as a real-time stream of measurement data received during a polishing process performed on the substrate.

Such technology may provide numerous benefits over conventional systems and techniques. For example, the film detection techniques may be used to provide in situ monitoring of film thickness during processing operations. Additionally, the optical-based film measurement techniques according to the present technology may be used to detect endpoints for polishing and/or other processing operations. These and other embodiments, along with many of their advantages and features, are described in more detail in conjunction with the below description and attached figures.

### BRIEF DESCRIPTION OF THE DRAWINGS

A further understanding of the nature and advantages of the disclosed technology may be realized by reference to the remaining portions of the specification and the drawings.

FIG. 1 shows a schematic cross-sectional view of an exemplary polishing system according to some embodiments of the present technology.

FIG. 2 shows a schematic partial cross-sectional view of exemplary processing system according to some embodiments of the present technology.

FIG. 3 shows a graph of a reflected signal model according to some embodiments of the present technology.

FIG. 4A shows a schematic partial cross-sectional view of an exemplary processing system according to some embodiments of the present technology.

FIG. 4B shows a schematic partial cross-sectional view of an exemplary processing system according to some embodiments of the present technology.

FIG. 5 is a flowchart of an exemplary method of determining a thickness of a film on a semiconductor substrate according to some embodiments of the present technology.

FIG. 6 illustrates a substrate undergoing a polishing process, according to some embodiments.

FIG. 7 illustrates a graph of the sensor output from the semiconductor substrate processing system at different radial distances on the substrate, according to some embodiments.

FIG. 8 illustrates a graph of actual measurement data during a polishing process, according to some embodiments.

FIG. 9 illustrates a simplified block diagram of a model-based system for determining a film thickness based on photosensor measurement data, according to some embodiments.

FIG. 10 illustrates an exemplary computer system according to some embodiments of the present technology.

Several of the figures are included as schematics. It is to be understood that the figures are for illustrative purposes, and are not to be considered of scale unless specifically stated to be of scale. Additionally, as schematics, the figures are provided to aid comprehension and may not include all aspects or information compared to realistic representations, and may include exaggerated material for illustrative purposes.

In the appended figures, similar components and/or features may have the same reference label. Further, various components of the same type may be distinguished by following the reference label by a letter that distinguishes among the similar components. If only the first reference label is used in the specification, the description is applicable to any one of the similar components having the same first reference label irrespective of the letter.

### DETAILED DESCRIPTION

In conventional chemical mechanical polishing (CMP) operations it is often difficult to determine whether the polishing process is complete, i.e., whether a substrate layer has been planarized to a desired flatness or thickness, or when a desired amount of material has been removed. Some CMP operations may rely on determining an endpoint for polishing based on polishing time. However, such reliance on polishing time can lead to within-wafer non-uniformity (WIWNU) and wafer-to-wafer non-uniformity (WTWNU) issues due to variations in the slurry distribution, the polishing pad condition, the relative speed between the polishing pad and the substrate, the load on the substrate can cause variations in the material removal rate, and/or variations in the initial thickness of the substrate layer. Some substrate polishing systems may determine polishing endpoints by using spectrometry. While these systems may adequately measure the thickness of a film on a substrate, such systems are often expensive and complicated to engineer.

The present technology overcomes these issues with conventional polishing systems by providing an optical sensor for measuring film thickness of an outermost layer of film. The presence of a film may be detected from a reflected and/or transmitted optical signal (e.g., a collimated or focused laser beam) and by controlling/tuning parameters such as angle of incidence, wavelength and dispersive properties of an incidence medium. This may enable the optical sensor to be used for polish endpointing for blanket and/or patterned films. The film thickness measurements may be executed before, during, and/or after a processing operation, which may enable film thickness to be monitored in situ during a polishing and/or other processing operation. The working principle of the optical sensor system may be based on interference, diffraction, evanescent wave coupling and total internal reflection at different interfaces of a stack of films on a substrate. The optical sensor may include a light source that is set up to illuminate a measurement point on the substrate at a non-zero angle of incidence and through a high or low refractive index medium, such as an index matching fluid.

In order to detect a top film with lower effective optical density compared to a sublayer, a refractive index of the matching fluid may be high enough such that magnitude of a tangential wave vector of the optical signal is greater than the magnitude of the effective wavenumber in the top film. The reflected signal will undergo a total internal reflection with zero transmission if the top film is relatively thick. If the top film is relatively thin but non-zero, the incident light will then get partially reflected and transmitted due to the evanescent coupling of light. The partial reflection/transmission may be determined by the sublayer properties. In order to differentiate the top film from the sublayer, the amplitude of the tangential wave vector needs to be smaller than the magnitude of the effective wavenumber in the sublayer so that a partial reflection/transmission is feasible. If the thickness of the top film is zero, the reflected/transmitted signal may be determined from sublayer properties which is a combination of interference and diffraction. The sensor can be designed to be less sensitive to sublayer variations. The reflected/transmitted signal could be collected for data analysis to determine a thickness of the top film. More generally, “high refractive index” of the fluid may be defined such that the magnitude of the tangential wave vector of the optical signal is between the magnitude of the effective wavenumber in the top film and the magnitude of the effective wave number in the sublayer. Therefore, in some embodiments, the magnitude of the tangential wave vector of the optical signal may be larger than the magnitude of the effective wavenumber in the top film and less than the magnitude of the effective wavenumber in the sublayer, while in other embodiments the magnitude of the tangential wave vector of the optical signal may be less than the magnitude of the effective wavenumber in the top film and greater than the magnitude of the effective wavenumber in the sublayer.

Although the remaining disclosure will routinely identify specific film measurement processes utilizing the disclosed technology, it will be readily understood that the systems and methods are equally applicable to a variety of other semiconductor processing operations and systems. Accordingly, the technology should not be considered to be so limited as for use with the described polishing systems or processes alone. The disclosure will discuss one possible system that can be used with the present technology before describing systems and methods or operations of exemplary process sequences according to some embodiments of the present technology. It is to be understood that the technology is not limited to the equipment described, and processes discussed may be performed in any number of processing chambers and systems, along with any number of modifications, some of which will be noted below.

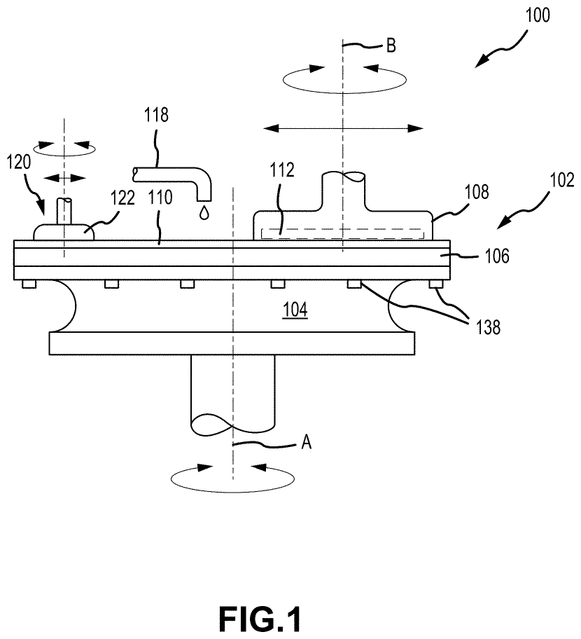

FIG. 1 shows a schematic cross-sectional view of an exemplary polishing system 100 according to some embodiments of the present technology. Polishing system 100 includes a platen assembly 102, which includes a lower platen 104 and an upper platen 106. Lower platen 104 may define an interior volume or cavity through which connections can be made, as well as in which may be included end-point detection equipment or other sensors or devices, such as eddy current sensors, optical sensors, or other components for monitoring polishing operations or components. For example, and as described further below, fluid couplings may be formed with lines extending through the lower platen 104, and which may access upper platen 106 through a backside of the upper platen. Platen assembly 102 may include a polishing pad 110 mounted on a first surface of the upper platen. A substrate carrier 108, or carrier head, may be disposed above the polishing pad 110 and may face the polishing pad 110. The platen assembly 102 may be rotatable about an axis A, while the substrate carrier 108 may be rotatable about an axis B. The substrate carrier may also be configured to sweep back and forth from an inner radius to an outer radius along the platen assembly, which may, in part, reduce uneven wear of the surface of the polishing pad 110. The polishing system 100 may also include a fluid delivery arm 118 positioned above the polishing pad 110, and which may be used to deliver polishing fluids, such as a polishing slurry, onto the polishing pad 110. Additionally, a pad conditioning assembly 120 may be disposed above the polishing pad 110, and may face the polishing pad 110.

In some embodiments of performing a chemical-mechanical polishing process, the rotating and/or sweeping substrate carrier 108 may exert a downforce against a substrate 112, which is shown in phantom and may be disposed within or coupled with the substrate carrier. The downward force applied may depress a material surface of the substrate 112 against the polishing pad 110 as the polishing pad 110 rotates about a central axis of the platen assembly. The interaction of the substrate 112 against the polishing pad 110 may occur in the presence of one or more polishing fluids delivered by the fluid delivery arm 118. A typical polishing fluid may include a slurry formed of an aqueous solution in which abrasive particles may be suspended. Often, the polishing fluid contains a pH adjuster and other chemically active components, such as an oxidizing agent, which may enable chemical mechanical polishing of the material surface of the substrate 112.

The pad conditioning assembly 120 may be operated to apply a fixed abrasive conditioning disk 122 against the surface of the polishing pad 110, which may be rotated as previously noted. The conditioning disk may be operated against the pad prior to, subsequent, or during polishing of the substrate 112. Conditioning the polishing pad 110 with the conditioning disk 122 may maintain the polishing pad 110 in a desired condition by abrading, rejuvenating, and removing polish byproducts and other debris from the polishing surface of the polishing pad 110. Upper platen 106 may be disposed on a mounting surface of the lower platen 104, and may be coupled with the lower platen 104 using a plurality of fasteners 138, such as extending through an annular flange shaped portion of the lower platen 104.

The polishing platen assembly 102, and thus the upper platen 106, may be suitably sized for any desired polishing system, and may be sized for a substrate of any diameter, including 200 mm, 300 mm, 450 mm, or greater. For example, a polishing platen assembly configured to polish 300 mm diameter substrates, may be characterized by a diameter of more than about 300 mm, such as between about 500 mm and about 1000 mm, or more than about 500 mm. The platen may be adjusted in diameter to accommodate substrates characterized by a larger or smaller diameter, or for a polishing platen 106 sized for concurrent polishing of multiple substrates. The upper platen 106 may be characterized by a thickness of between about 20 mm and about 150 mm, and may be characterized by a thickness of less than or about 100 mm, such as less than or about 80 mm, less than or about 60 mm, less than or about 40 mm, or less. In some embodiments, a ratio of a diameter to a thickness of the polishing platen 106 may be greater than or about 3:1, greater than or about 5:1, greater than or about 10:1, greater than or about 15:1, greater than or about 20:1, greater than or about 25:1, greater than or about 30:1, greater than or about 40:1, greater than or about 50:1, or more.

The upper platen and/or the lower platen may be formed of a suitably rigid, light-weight, and polishing fluid corrosion-resistant material, such as aluminum, an aluminum alloy, or stainless steel, although any number of materials may be used. Polishing pad 110 may be formed of any number of materials, including polymeric materials, such as polyurethane, a polycarbonate, fluoropolymers, polytetrafluoroethylene polyphenylene sulfide, or combinations of any of these or other materials. Additional materials may be or include open or closed cell foamed polymers, elastomers, felt, impregnated felt, plastics, or any other materials that may be compatible with the processing chemistries. It is to be understood that polishing system 100 is included to provide suitable reference to components discussed below, which may be incorporated in system 100, although the description of polishing system 100 is not intended to limit the present technology in any way, as embodiments of the present technology may be incorporated in any number of polishing systems that may benefit from the components and/or capabilities as described further below.

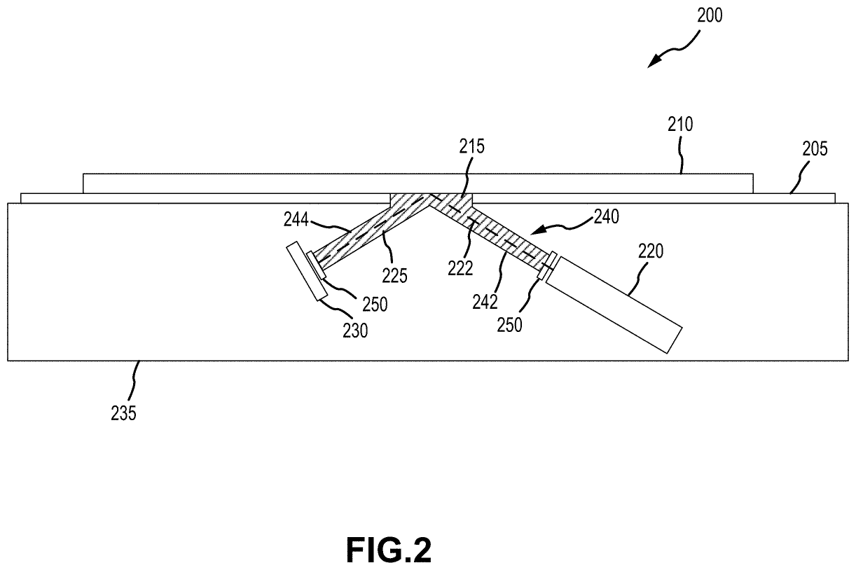

FIG. 2. Illustrates a schematic cross-sectional view of an exemplary semiconductor substrate processing system 200 according to some embodiments of the present technology. FIG. 2 may illustrate further details relating to components in system 100, such as for polishing pad 110. System 200 is understood to include any feature or aspect of system 100 discussed previously in some embodiments. The system 200 may be used to perform semiconductor processing operations including polishing operations as previously described, as well as other deposition, etch, removal, and cleaning operations. System 200 may show a partial view of the system components being discussed and that may be incorporated in a semiconductor processing system. Processing system 200 may include a substrate support 205. Substrate support 205 may receive and support a substrate 210 during one or more processing operations. In some embodiments, the substrate support 205 may be a polishing pad of a polishing system, similar to described above. The substrate support 205 may take other forms, such as a support for deposition and/or etching operations in various embodiments. The substrate support 205 may define an aperture 215 through a thickness of the substrate support 205 through which a portion of the substrate 210 may be accessed.

The processing system 200 may include a light assembly having a light source 220 that emits an optical signal 222 that is directed to the semiconductor substrate 210 via the aperture 215. The light source 220 may emit collimated, converging, and/or diverging light that illuminates a measurement point (aligned with the aperture 215) of the semiconductor substrate 210 at a non-zero angle of incidence through a fluid 225. For example, in some embodiments, the light source 220 may include a laser. The optical signal 222 may have a diameter of between or about 1 micron and 10 mm, between or about 10 microns and 5 mm, between or about 100 microns and 1 mm, between or about 200 microns and 900 microns, between or about 300 microns and 800 microns, between about 400 microns and 700 microns, or between or about 500 microns and 600 microns. The optical signal 222 may be directed to the semiconductor substrate 210 at a high angle of incidence. By directing the optical 222 to the substrate 210 at a high angle of incidence, a reflected portion of the optical signal 222 may be modeled as a decreasing function of the outermost film thickness such that as the film thickness decreases, the magnitude of the reflected portion also decreases. If a low angle of incidence is used, the optical signal 222 may be sinusoidal in nature, which may result in a number of different film thicknesses being represented by a single magnitude of reflected portion of the optical signal 222. Additionally, higher angles of incidence may enable fluid 225 to be selected to have a high index of refraction. As used herein, a “high” angle of incidence may be understood to be an angle that enables the condition that a refractive index of the fluid 225 is sufficiently high that an amplitude of a tangential wave vector of the optical signal is greater than a magnitude of a wavenumber of the outermost layer of film and less than a magnitude of a wavenumber of a sublayer of film. Thus, the angle of incidence may be varied based on the refractive index of the outermost film layer, sublayer of film, and/or fluid 225. In particular embodiments, a high angle of incidence may be greater than or about 10 degrees, greater than or about 20 degrees, greater than or about 30 degrees, greater than or about 40 degrees, greater than or about 50 degrees, greater than or about 60 degrees, greater than or about 70 degrees, greater than or about 80 degrees, or more. The optical signal 222 may be directed to the semiconductor substrate 210 either directly from the light source 220 and/or via one or more optical elements, such as lenses, prisms, diffraction gratings, mirrors, and the like that may be included in the light assembly. As illustrated, the light source 220 emits the optical signal 222 directly to the semiconductor substrate 210 at the high angle of incidence.

The processing system 200 may include a photodetector 230. The photodetector 230 may be aligned with an angle of reflectance of the optical signal 222 such that at least a portion of the optical signal 222 reflected by the semiconductor substrate 210 is received by the photodetector 230. The reflected/transmitted optical signal 222 may be collected using imaging or non-imaging techniques for data analysis.

In some embodiments, the substrate support 205 may include and/or be coupled with a lower support structure 235, which may be similar to upper platen 106 described above. The lower support structure 235 may define a channel 240 that optically couples the light source 220, aperture 215, and photodetector 230. For example, the channel 240 may include a first branch 242 that extends along the angle of incidence of the optical signal 222 and a second branch 244 that extends along the angle of reflectance of the optical signal 222, with the first branch 242 and the second branch 244 meeting proximate the aperture 215. In some embodiments, the channel 240 may be generally v-shaped to match a path of the optical signal 222 from the light source 220 to the photodetector 230. In some embodiments, one or more optical elements, such as mirrors, lenses, and the like, may be provided within and/or outside of the channel 240 to direct and/or focus light from the light source 220 to the aperture 215 and/or photodetector 230, which may provide greater flexibility in the positioning of the light source 220 and/or photodetector 230. For example, the light source 220 and/or photodetector 230 may be oriented at a normal angle relative to the substrate 210, with one or more mirrors being used to direct the light toward the substrate 210 at a high angle of incidence.

Distal ends of the first branch 242 and/or second branch 244 may include a window 250 that seals the respective end of the channel 240. For example, a window 250 may be positioned between an end of the first branch 242 and the light source 220 and/or a window 250 may be positioned between an end of the second branch 244 and the photodetector 230. Each window 250 may be formed from quartz and/or other optically transmissive material. The channel 240 may be filled with the fluid 225 in some embodiments, with the fluid 225 extending from the windows 250 and filling the aperture 215, with a top surface of the fluid 225 contacting an outermost film layer of the semiconductor substrate 210.

The fluid 225 may be positioned within the aperture 215 and may contact the measurement surface of the semiconductor substrate 210. The fluid 225 be a high refractive index fluid that is selected based on a composition of the film stack. Examples of acceptable fluids 225 may include the Refractive Index Liquid Set RF-1, Catalog #18001 from Cargille Labs and/or Gem Refractometer Liquid, Catalog #19160 from Cargille Labs. Fluid 225 may be selected to have an index of refraction that is sufficiently high that a magnitude of a tangential wave vector of the optical signal 222 is greater than a magnitude of a wavenumber of a top or outermost film layer of the semiconductor substrate 210. In some embodiments, the fluid 225 may have an index of refraction that closely matches (within about 10%) an index of refraction of a material forming the outermost layer of the semiconductor substrate 210. In some embodiments, rather than or in addition to the fluid 225, the processing system 200 may include a dispersive/diffractive element such as a diffraction grating and/or prism.

In operation, the light source 220 may direct the optical signal through the fluid 225 to the measurement position of the semiconductor substrate 210 via the aperture 215. Some amount of the optical signal 222 may be reflected to and received by the photodetector 230. The optical signal will undergo a total internal reflection with zero transmission when the outermost layer of film of the semiconductor substrate 210 is relatively thick. If the outmost layer of film is relatively thin, but non-zero, the incident light will be partially reflected and transmitted due to the evanescent coupling of light. The partial reflection/transmission is determined by properties of a sublayer of film of the semiconductor substrate 210. In order to differentiate the outermost layer of film from the sublayer, the amplitude of the tangential wave vector may be smaller than the magnitude of the effective wavenumber in the sublayer so that a partial reflection/transmission is feasible. If the thickness of the outermost film layer is zero, the reflected/transmitted signal is determined from sublayer properties which is a combination of interference and diffraction. The sensor can be designed to be less sensitive to sublayer variations. The detected signals are then analyzed through a software routine to determine the thickness of the outermost film layer.

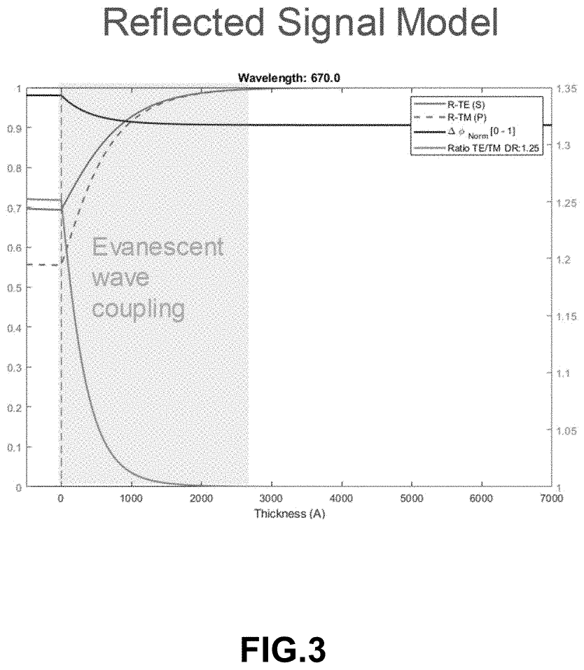

FIG. 3 illustrates a graph of a reflected signal model that illustrates how a thickness of the outermost film layer may be determined. The signal model may represent an oxide outermost layer on top of a nitride or silicon film sublayer, however signal models of other film arrangements may be similar. The reflected signal model shown may monitor the transverse electric mode (TE) component and the transverse magnetic mode (TM) component of the signal, as well as a ratio between the TE and TM components in some embodiments. As the TE and TM components of the optical signal 222 received by the photodetector 230 approach 1.0 (100% total internal reflection), it may be determined that the outermost layer of film of the semiconductor substrate 210 is thick. For example, in a particular embodiment, the thickness of the outermost layer of film may be greater than or about 2500 Å, although the thickness may be dependent on a composition of the outermost film layer, an angle of incidence of the optical signal 222, and/or a refractive index of the fluid 225. As the thickness of the outermost film layer decreases (such as after polishing operations), the amount of optical signal 222 that is received by the photodetector 230 may also be reduced. The reduction of the received portion of the optical signal 222 may be attributable to the partial reflection of the optical signal 222 due to the evanescent coupling of light when the thickness of the outermost film layer is no longer sufficient to totally reflect all of the optical signal 222. In other words, as the outermost film layer thins, less of the optical signal 222 may be reflected to the photodetector 230. The amount of the optical signal 222 received at the photodetector 230 may be mapped to a curve such as shown in the graph and/or may otherwise be used to calculate a thickness of the outermost layer of film. For example, the magnitude and/or percentage of the optical signal 222 received at photodetector 230 may be compared to known values to determine a corresponding thickness of the outermost film layer. Once the amount of optical signal 222 received by the photodetector 230 reaches a certain threshold, it may be determined that the outermost film layer has been fully removed. For example, as illustrated, when the TE component of the reflected signal is approximately 0.7 and/or when the TM component of the reflected signal is approximately 0.56, it may be determined that the outermost film layer has been fully removed (i.e., has a thickness of zero A).

While described with an amplitude of the tangential wave vector being greater than a magnitude of a wavenumber of the outermost layer of film and less than a magnitude of a wavenumber of a sublayer of film, it will be appreciated that a similar result may be achieved with an amplitude of the tangential wave vector being less than a magnitude of a wavenumber of the outermost layer of film and greater than a magnitude of a wavenumber of a sublayer of film. In such embodiments, the curve of the TE and TM components of the optical signal 222 may be inverted. This may enable film thicknesses to be analyzed for different arrangements of film layers.

The film thickness detection described above may be useful for endpoint determinations in polishing operations. For example, a polishing operation may be used to achieve a desired film profile across a substrate. The profile may be uniform across the substrate and/or may include a number of areas of different film thickness. In some embodiments, at least a portion of an outermost layer of film may be entirely removed by polishing to expose a sublayer of the substrate. The film thickness measurement technique described above may be performed in situ at a number of locations of the substrate to monitor a thickness of the film to determine when the film thickness in a given region of the substrate has reached a desired level, at which time the polishing may be halted for that region of the substrate. While discussed primarily in relation to polishing systems, it will be appreciated that the film thickness measurement techniques described herein may be utilized to measure a film thickness in any type of wet or dry metrology application.

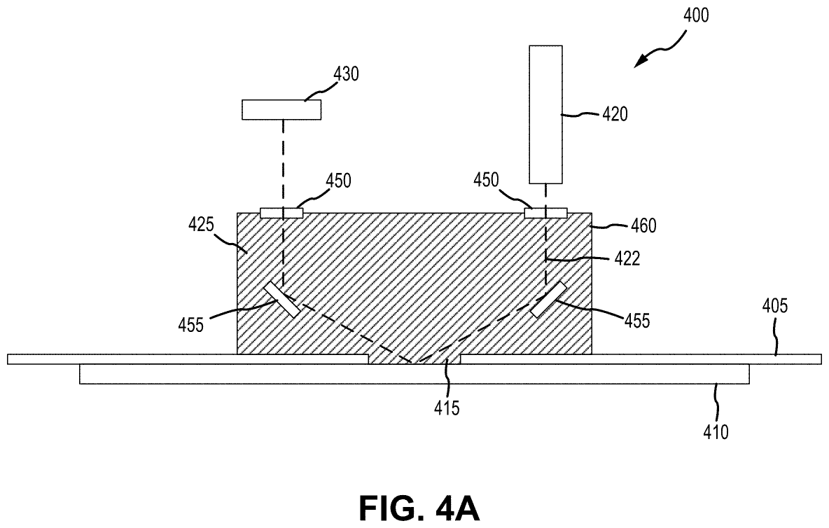

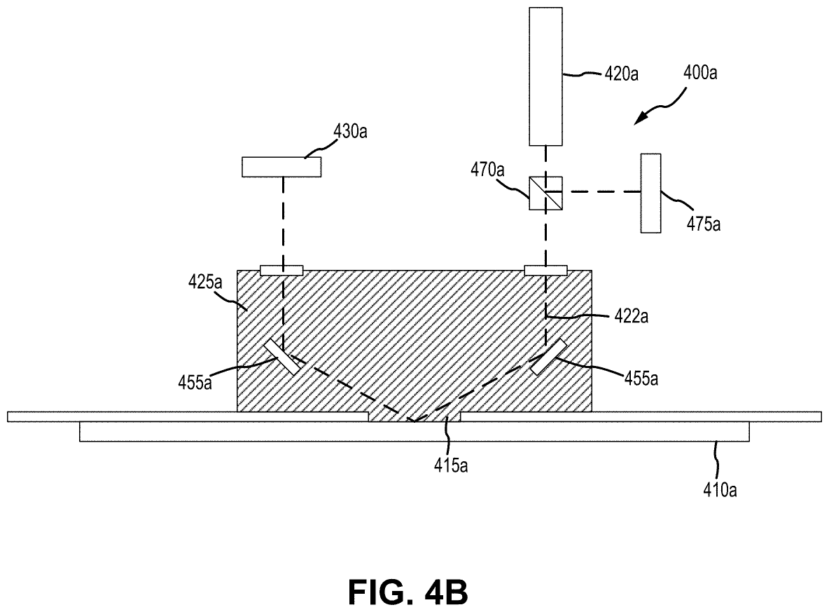

FIG. 4A illustrates a schematic cross-sectional view of an exemplary semiconductor substrate processing system 400 according to some embodiments of the present technology. FIG. 4A may illustrate further details relating to components in system 100 or 200. System 400 is understood to include any feature or aspect of system 100 discussed previously in some embodiments. The system 400 may be used to perform semiconductor processing operations including polishing operations as previously described, as well as other deposition, etch, removal, and cleaning operations. System 400 may show a partial view of the system components being discussed and that may be incorporated in a semiconductor processing system. Processing system 400 may include a substrate support 405 that defines an aperture 415. The substrate support 405 may be positioned above a substrate 410 during one or more processing operations, with the substrate 410 being movable relative to the aperture 415. The processing system 400 may include a light assembly having a light source 420 that emits an optical signal 422 that is directed to the semiconductor substrate 410 via the aperture 415. As illustrated, the optical signal 422 may directed toward the aperture 415 using one or more mirrors 455, which may reflect the optical signal 422 to the semiconductor substrate 410 at a high angle of incidence. The processing system 400 may include a photodetector 430. The photodetector 430 may be directly aligned with an angle of reflectance of the optical signal 422 and/or one or more mirrors 455 may be used to reflect at least a portion of the optical signal 422 reflected off of the semiconductor substrate 410 to the photodetector 430.

A fluid 425, such as a high refractive index fluid, may be positioned within the aperture 415 and may contact the measurement surface of the semiconductor substrate 410. The fluid 425 may be provided within a container 460 in some embodiments and/or may be pumped in (continuously and/or intermittently during measurement operations) and/or otherwise supplied to the aperture 415 and outermost film layer of the semiconductor substrate 410 during measurement operations. In embodiments in which a container 460 is used, a bottom of the container 460 may define an opening that enables some of the fluid 425 to fill the aperture 415 and contact a surface of the substrate 410. In some embodiments in which the fluid 425 is provided within a container, windows 450, such as quartz windows, may be positioned at a top end of the container in optical alignment with the light source 420 and/or photodetector 430. In embodiments using mirrors 455, the mirrors 455 may be positioned below a surface of the fluid 425 such that the optical signal 422 enters and exits the fluid 425 at a normal angle relative to the surface of the fluid 425, which may minimize or prevent refraction of the optical signal 422 at the fluid interface.

In some embodiments, the emitted power of the optical signal 422 may not be known. FIG. 4B illustrates a schematic cross-sectional view of an alternative embodiment of processing system 400a that may measure the emitted power of the optical signal 422a to enable a measurement of the film thickness to be determined based on an amount of the optical signal 422a received by the photodetector 430a. For example, processing system 400a may include a beam splitter 470a positioned between the light source 420a and the fluid 425a. The beam splitter 470a may split the optical signal 422a into two or more beams, with one beam being directed toward the substrate 410a (such as via one or more mirrors 455a) and at least one beam directed to an additional photodetector 475a. Based on the amount of the optical signal 422a received at the photodetector 475a, a total emitted power of the optical signal 422a and/or the beam directed toward the substrate 410a may be determined. This emitted power may be used in determining how much of the optical signal 422a is received at the photodetector 430a when calculating a film thickness of the outermost film layer of the substrate 410a. For example, if the beam splitter 470a splits the optical signal 422a into two equal beams, the amount of optical signal received at photodetector 430a may be compared to the emitted power of the optical signal 422a that is received at photodetector 475a as at most half of the initial optical signal 422a may be received at the photodetector 422a.

Processing system 400 may operate in a manner similar to processing system 200 to determine a thickness of an outermost film layer of the substrate 410. For example, the optical signal 422 may be directed to the outermost film layer of the substrate 410, with at least some of the optical signal 422 being received by the photodetector. An amount of the optical signal 422 that was received as reflected light by the photodetector may be determined and used to calculate a thickness of the outermost film layer. While shown with the substrate support 405, light source 420, and photodetector 430 being positioned above the substrate support 410, it will be appreciated that processing system 400 may be arranged such that the substrate support 405, light source 420, and photodetector 430 are positioned below the substrate support 410 in a manner similar to that shown in processing system 200.

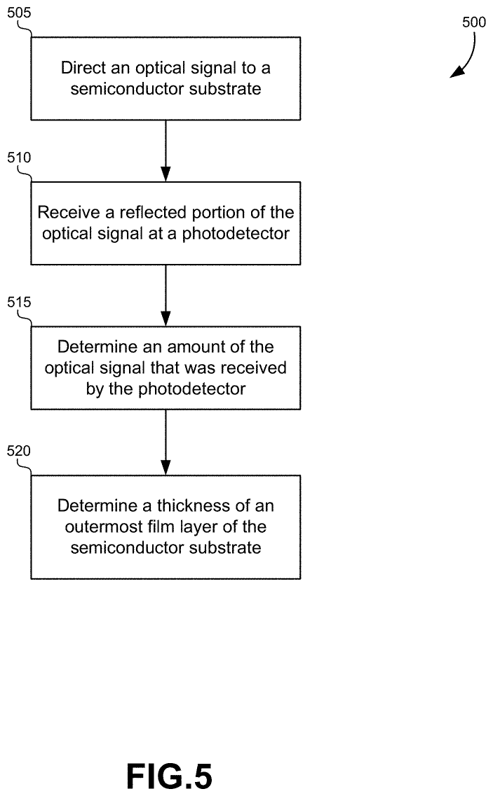

FIG. 5 shows operations of an exemplary method 500 of measuring film thickness of a substrate according to some embodiments of the present technology. The method may be performed in a variety of processing systems, including polishing system 100 and/or processing systems 200 or 400 described above, which may include optical sensors according to embodiments of the present technology, such as any combination of a light source and photodetector discussed previously. Method 500 may include a number of optional operations, which may or may not be specifically associated with some embodiments of methods according to the present technology.

Method 500 may include directing an optical signal to a semiconductor substrate that is positioned on a substrate support at operation 505. For example, a light source may emit an optical signal, such as collimated light, that is directed to a surface of the substrate, either directly or indirectly. The surface of the substrate may be exposed to a high refractive index fluid. The fluid may be supplied within a container, channel, and/or may be pumped onto the surface of the substrate. In some embodiments, the high refractive index fluid may have a refractive index that is sufficiently high that an amplitude of a tangential wave vector of the optical signal is greater than a magnitude of a wavenumber of the outermost layer of film of the semiconductor substrate. The amplitude of the tangential wave vector of the optical signal may be less than a magnitude of a wavenumber of a sublayer of film of the semiconductor substrate. In embodiments in which the optical signal is indirectly aimed at the substrate, the optical signal may be reflected toward the substrate using one or more mirrors which may be disposed within the fluid.

Method 500 may include receiving a reflected portion of the optical signal from the semiconductor substrate using a photodetector at operation 510. An amount of the optical signal that was received by the photodetector in the form of the reflected portion may be determined at operation 515. For example, a computing system may compare the emitted power of the optical signal emitted from the light source to the power of the reflected portion to determine how much of the optical signal was reflected onto the photodetector. Based on the amount of the optical signal that was received by the photodetector, a thickness of an outermost layer of film of the substrate may be determined at operation 520. For example, a lower magnitude of the amount of the optical signal that was received by the photodetector as the reflected portion may correspond with the outermost layer of film having a lower thickness. In some embodiments, the amount of the optical signal received at the photodetector may be mapped to a curve, compared to known signal/film thickness values, and/or may otherwise be used to calculate a thickness of the outermost layer of film. For example, the thickness of the outermost film layer of the semiconductor substrate may be determined using a train the model as described in detail below.

The film thickness measurement may be repeated any number of times and/or performed continuously in various embodiments. Additionally, film thickness measurements may be taken at a number of locations about the surface of the substrate. For example, the substrate and/or substrate support may be moved relative to one another such that different locations of the substrate may be measured. In some embodiments, the film thickness measurements may be used to determine polishing endpoints. For example, the substrate may be polished using a polishing system (similar to polishing system 100 described herein). When the film thickness measurement indicates that a thickness of the outermost layer of film of the semiconductor substrate has reached a predetermined threshold (such as a desired endpoint thickness), the polishing operating may be halted. It will be appreciated that the film measurement methods described above may be used before, during, and/or after a processing operation. Additionally, the film measurement methods described above are not limited to polishing applications and may be utilized in any wet or dry metrology operation.

A primary purpose of the semiconductor substrate processing system 400 described above may be to identify regions on a substrate where a film still currently exists during a processing step. However, a technical problem exists where a film may be formed on a substrate unevenly. For example, the substrate may include areas where the film is relatively thick compared to other areas where the film is relatively thin. This lack of uniformity in the thickness of the film may be due to a number of different factors. For example, each substrate may include different circuit features that cause the film to build up nonuniformly in different locations. The deposition process itself may include factors that cause the film to be distributed nonuniformly on the surface of the substrate. Some substrates may be subject to warping or other physical deformities that cause the film to be formed differently on the substrate in different locations. Therefore, as a measurement is made across the substrate after the deposition process, the thickness of the film at different radii may be nonuniform.

In many cases, a film may be removed from the substrate after deposition. For example, a photoresist may be applied to a substrate and used during a lithography or etch process. This photoresist layer may then be removed by, for example, a chemical mechanical polishing process. Even if the film was deposited evenly on the substrate, variations in the polishing process may remove the film unevenly from the substrate. For example, pressure may be applied to different areas on the substrate during the polishing process in order to remove more or less material. The semiconductor substrate processing system 400 described above may include a polishing pad that measures the thickness of the film on the substrate during the polishing process. Therefore, it is important for such polishing processes to accurately determine when the film has been removed from the substrate to prevent the polishing process from removing additional material layers from the substrate. However due to either nonuniformity in the film or nonuniformity in the polishing process, the thickness of the film may vary in different locations on the substrate. Therefore, the semiconductor substrate processing system 400 may be used to provide a real-time stream of measurement data to a controller that controls various parameters for the polishing process to provide uniformity across the substrate.

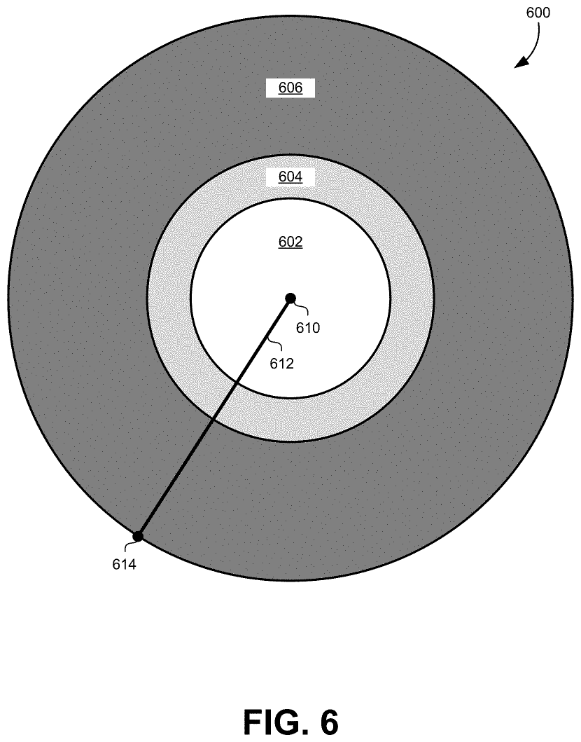

FIG. 6 illustrates a substrate undergoing a polishing process, according to some embodiments. Because varying pressures may be applied to different areas on the substrate 600, or because of variations in the starting film thickness, different areas on the substrate may include films of different thicknesses. For example, this substrate 600 may be representative of a substrate before the polishing process is complete. An area 602 located around a center of the substrate 600 may be characterized as having the outermost film completely removed, thereby exposing the underlying layer of the substrate 600. An area 604 may be characterized as having a thin film of material remaining on the substrate 600. Similarly, an area 606 may be characterized as having a thick film of material remaining on the substrate 600. For example, the polishing process may exert greater force on the area 602 located around the center of the substrate than on the periphery of the substrate. Alternatively or additionally, film on the substrate 600 may have been thinner inside the area 602 than in the area 606 before the polishing process began. In either case, the polishing process may be controlled to compensate for this uneven film thickness and/or removal.

As used herein, the terms “thick,” “thin,” etc., may be interpreted relative to each other. For example, a thin film may include at least some measurable layer of film while still being less than an area characterized as having thick film. In some embodiments, a thin oxide may be characterized as being less than 2000 Å thick. A thick oxide may be characterized as being between about 2000 Å and about 7000 Å thick.

Because the thickness of the film on the substrate 600 may vary based on the radius at which the measurement is taken, some embodiments may either move the measurement window relative to the substrate 600 or move the substrate 600 relative to the measurement window. For example, the movement of the substrate 600 on the polishing pad above the measurement window may allow measurements to be taken beginning at a center point 600 to beyond a point 614 at or beyond the edge of the wafer 600 along a measurement path 612. Note that the measurement path 612 need not be a straight line, but may instead represent different radial distances at which a measurement is made, assuming that the film thickness is relatively constant at different locations on the substrate at the same radius. Therefore, the semiconductor substrate processing system 400 described above may generate a real-time stream of measurement data, where each time series measurement includes a value based on a received signal from the photoreceptor and a location or radius on the substrate 600. For example, when moving at a constant rotational velocity, a time associated with each measurement may be translated into a location on the substrate as the measurement moves between radii on the measurement path 612.

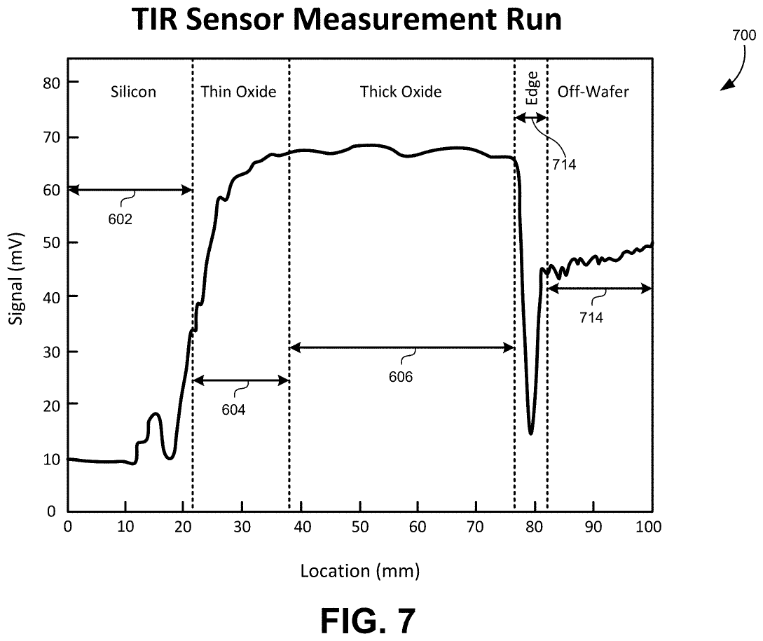

FIG. 7 illustrates a graph 700 of the sensor output from the semiconductor substrate processing system 400 at different radial distances on the substrate 600, according to some embodiments. As described above, the signal strength from the semiconductor substrate processing system 400 may represent a reflected signal power that is indicative of a thickness of the substrate.

The measurements illustrated in FIG. 7 may be consistent with the film distribution on the substrate 600 in FIG. 6. For example, the area 602 in the center of the substrate 600 (e.g., with a radius of less than about 22 mm) may have a signal strength that is relatively low, such as below about 20 mV. As the location of the measurement extends outward from the center point of the substrate 600, the thickness of the film may transition between the area 604 having a thin oxide into the area 606 where the oxide is thick. As the measurement moves off the edge of the substrate 600, the graph includes a region 714 illustrating the sensor measurements as the sensor “falls off” the edge of the substrate 600. The region 714 illustrates the noisy output of the sensor when the substrate 600 is no longer above the measurement window.

The waveform in graph 700 may represent a filtered version of the sensor output. For example, the sensor output may be processed using a low-pass filter that removes some of the noise and transient spikes from the measurement data. The waveform in graph 700 also represents a largely ideal response from the sensor and/or the measurement environment. Specifically, the waveform exhibits a smooth transition between the area 602 having no film through the area 604 having a thin film, and into the area 606 having a thick film. Therefore, a characterization of the thickness of the film may be made at any radial location on the substrate 600 by comparing the signal output from the sensor to a threshold. For example, below approximately 40 mV may indicate that the film is substantially removed. A sensor output between about 40 mV and about 65 mV may indicate that a thin film is present, and a sensor output above about 65 mV may indicate a thick film is present.

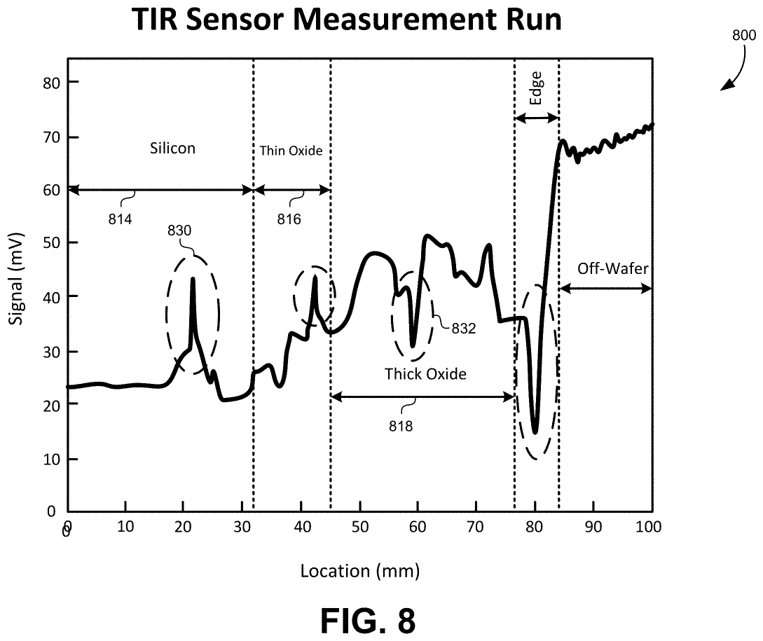

FIG. 8 illustrates a graph 800 of actual measurement data during a polishing process, according to some embodiments. The waveform in the graph 800 may have gone through a filtering process as described above to remove some of the noise and transients spikes. However, even when filtered, the waveform may still exhibit positive/negative spikes that may cause problems when using a simple thresholding method for identifying a thickness of the film. For example, a spike 830 may be recorded in area 814 where no film is present on the substrate. However, when using a threshold alone (e.g., about 25 mV in this example), this spike 830 may erroneously be interpreted as transitioning into the area 816 where a thin film of oxide is present. Similarly, spike 832 in the area 818 where a thick oxide film is present may be erroneously interpreted as indicating only a thin film of oxide or no oxide being present. This illustrates how it may be difficult to use a thresholding method of determining a film thickness in a noisy environment.

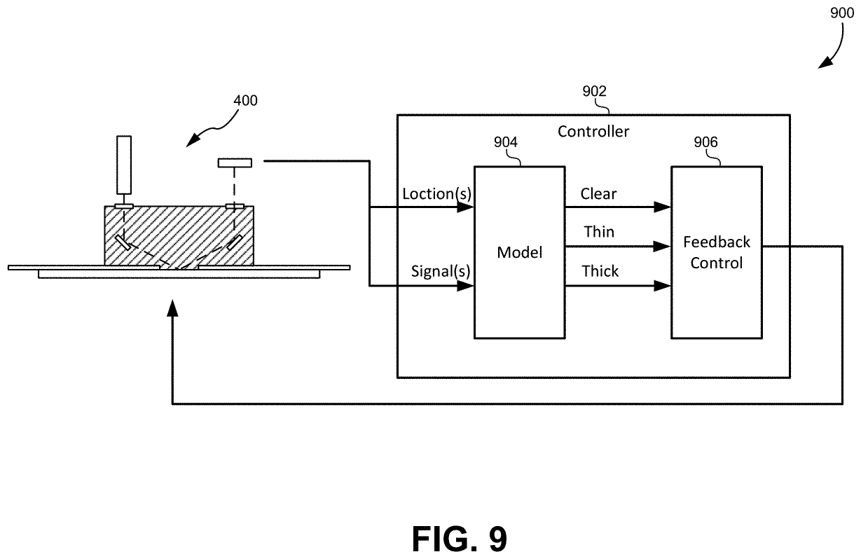

FIG. 9 illustrates a simplified block diagram 900 of a model-based system for determining a film thickness based on photosensor measurement data, according to some embodiments. Instead of using simple thresholding, a model 904 may be trained to receive measurement data from the photosensor and to output an indication of the thickness of the outermost layer of the film on the substrate. The model may be implemented as a classification model. In some embodiments, the classification model may comprise a binary classification model that distinguishes between a film being present at the location or the film not being present at the location. In other embodiments, the classification model may comprise a multi-class classification model that distinguishes between different thickness ranges of the film. For example, as illustrated in FIG. 9, the classification model may generate outputs that indicate a likelihood that the location is clear of the film (e.g., exposed silicon or substrate beneath the film), a likelihood that a thin film thickness is present, and/or a likelihood that a thick film thickness is present at the current location being measured on the substrate. The model 904 may be implemented using a neural network, which may be trained or refined using a classification algorithm such as logistic regression, Naïve Bayes, K-Nearest Neighbors, decision trees, support vector machines, random forest, and/or other similar algorithms.

The inputs to the model may include values associated with the output of the photosensor. For example, some embodiments may receive the raw measured or sampled values from the photosensor. These values may be filtered using a low-pass filter in noisy environments. Alternatively, the model 904 may receive processed values from the photosensor. For example, some embodiments may receive an amount of the optical signal that is received by the photosensor relative to an amount transmitted by the light source, such as a difference between these two values. Thus, the measurement data provided to the model 904 may be normalized with respect to a signal transmitted by the light source or may be provided as an absolute value (e.g., a sensor response signal in mV).

In some embodiments, the model 904 may be implemented as a long short-term memory (LSTM) or recurrent neural network configured to process a sequence of real-time measurement data from the photosensor. As illustrated in FIG. 9, the model 904 may receive a location on the substrate and an associated data measurement from the photosensor. The model 904 may then provide a likelihood for each output classification based on the current location and data measurement along with previous locations and measurements provided from the substrate. Alternatively, the neural network 904 may be implemented as a feedforward neural network that processes a batch of locations simultaneously. For example, a feedforward neural network may receive a batch of measurements taken at each incremental radius as the measurement moves from the center of the substrate to the edge of the substrate (e.g., the measurement path 612 from FIG. 6). Similar to processing a 2D image, the model 904 may identify features in the data that divide the data into areas that are clear of the film, areas having a thin film, and/or areas having a thick film. In FIG. 9, each of these outputs may provide a location on the wafer (e.g., in millimeters) where the transition between these areas is identified. For example, the “Clear” output may indicate a distance from a center of the substrate within which the substrate is clear of the film. Alternatively, the model 904 may receive the batch of measurements in a single location on the substrate and provide probabilities for the clear/thin/thick outputs for that single location after processing the data along the measurement path 612. Each of these different types of possible outputs may be collectively referred to as indications of the thickness of the outermost layer the film on the substrate.

The controller 902 may include a feedback control 906 configured to control a manufacturing process performed on the substrate based at least in part on the output of the model 904. For example, the feedback control 906 may use the output of the model 904 as an input to a control algorithm that controls a polishing rate, a polishing location, pressure applied to regions of the substrate, and/or other parameters of a polishing process. For example, the feedback control 906 may cause the polishing process to reduce pressure on the center of the substrate while increasing pressure on the periphery of the substrate in order to increase the polishing pressure on the portions of the film that are the thickest and decrease the polishing pressure on the portions of the film that are the thinnest or where the film is substantially removed.

The model 904 may be trained using a supervised training method that labels prior measurements performed on substrates being polished. For example, the graph 800 in FIG. 8 may be one of many sets of training data provided to the model 904. The measurements may be labeled using the vertical lines in graph 800 that indicate the divisions between the area 814 with an exposed substrate and the area 816 with a thin film, and so forth. These training data may be provided to the model to set the internal weights and node values for the neural network. The model 904 may also be retrained periodically using substrate measurements that were previously received by the model 904 during operation. These measurements may be reviewed and labeled based on the actual transitions between the clear/thin/thick film regions. The error between the actual transitions and the transitions previously calculated by the model 904 may be used to retrain the model 904 to continually improve the accuracy of the model.

Using the techniques described above, the model 904 may also be configured to accurately generate an indication of the thickness of the film. In addition to characterizing the transitions between the clear/thin/thick film regions, these outputs may also be used to estimate an absolute thickness of the film. For example, the model 904 may include an output that generates a normalized output between 0.0 and 1.0 indicating an estimated thickness of the film between the film's maximum thickness and the film's complete removal.

Using the model 904 may offer specific technical improvements over simply using thresholds to identify a thickness of the film at a location. For example, the training process may cause the model 904 to effectively ignore the peaks 830, 832 in the measurement data. Note that removing these peaks by low-pass filtering alone smooths the data too much, and thus degrades the accuracy with which exact transitions between the clear/thin/thick region may be identified. The model instead recognizes peaks that are likely within one of these regions and ignores them as transients caused by features unrelated to the film thickness. For example, these peaks may be generated by features on the underlying substrate (e.g., metal traces) that cause high reflectance unrelated to the film thickness.

Each of the methods described herein may be implemented by a computer system. Each step of these methods may be executed automatically by the computer system, and/or may be provided with inputs/outputs involving a user. For example, a user may provide inputs for each step in a method, and each of these inputs may be in response to a specific output requesting such an input, wherein the output is generated by the computer system. Each input may be received in response to a corresponding requesting output. Furthermore, inputs may be received from a user, from another computer system as a data stream, retrieved from a memory location, retrieved over a network, requested from a web service, and/or the like. Likewise, outputs may be provided to a user, to another computer system as a data stream, saved in a memory location, sent over a network, provided to a web service, and/or the like. In short, each step of the methods described herein may be performed by a computer system, and may involve any number of inputs, outputs, and/or requests to and from the computer system which may or may not involve a user. Those steps not involving a user may be said to be performed automatically by the computer system without human intervention. Therefore, it will be understood in light of this disclosure, that each step of each method described herein may be altered to include an input and output to and from a user, or may be done automatically by a computer system without human intervention where any determinations are made by a processor. Furthermore, some embodiments of each of the methods described herein may be implemented as a set of instructions stored on a tangible, non-transitory storage medium to form a tangible software product.

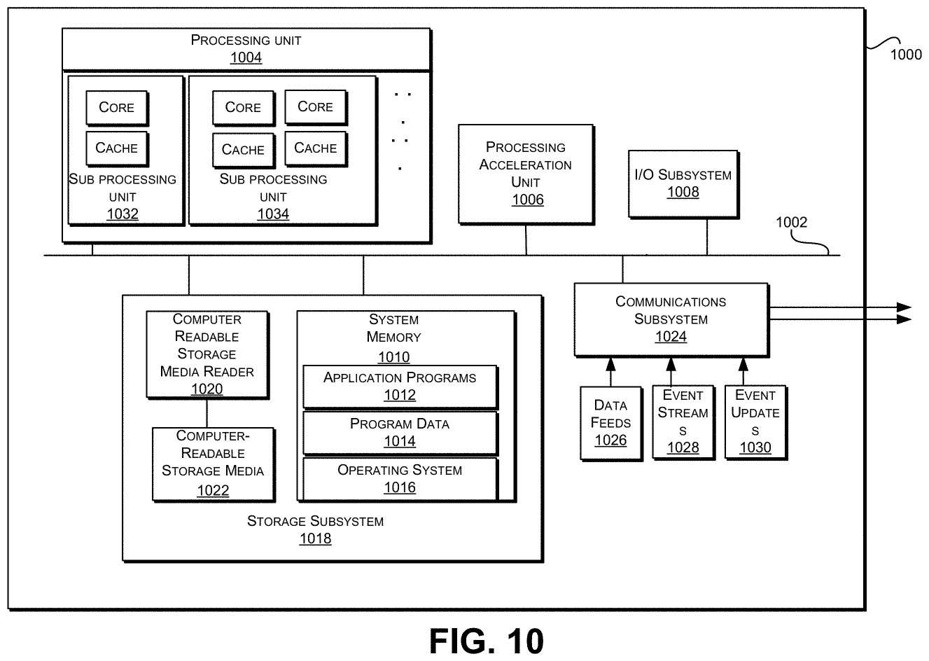

FIG. 10 illustrates an exemplary computer system 1000, in which various embodiments may be implemented. The system 1000 may be used to implement any of the computer systems described above. For example, the system 1000 may be used to implement the controller 902 in FIG. 9. As shown in the figure, computer system 1000 includes a processing unit 1004 that communicates with a number of peripheral subsystems via a bus subsystem 1002. These peripheral subsystems may include a processing acceleration unit 1006, an I/O subsystem 1008, a storage subsystem 1018 and a communications subsystem 1024. Storage subsystem 1018 includes tangible computer-readable storage media 1022 and a system memory 1010.

Bus subsystem 1002 provides a mechanism for letting the various components and subsystems of computer system 1000 communicate with each other as intended. Although bus subsystem 1002 is shown schematically as a single bus, alternative embodiments of the bus subsystem may utilize multiple buses. Bus subsystem 1002 may be any of several types of bus structures including a memory bus or memory controller, a peripheral bus, and a local bus using any of a variety of bus architectures. For example, such architectures may include an Industry Standard Architecture (ISA) bus, Micro Channel Architecture (MCA) bus, Enhanced ISA (EISA) bus, Video Electronics Standards Association (VESA) local bus, and Peripheral Component Interconnect (PCI) bus, which can be implemented as a Mezzanine bus manufactured to the IEEE P1386.1 standard.

Processing unit 1004, which can be implemented as one or more integrated circuits (e.g., a conventional microprocessor or microcontroller), controls the operation of computer system 1000. One or more processors may be included in processing unit 1004. These processors may include single core or multicore processors. In certain embodiments, processing unit 1004 may be implemented as one or more independent processing units 1032 and/or 1034 with single or multicore processors included in each processing unit. In other embodiments, processing unit 1004 may also be implemented as a quad-core processing unit formed by integrating two dual-core processors into a single chip.

In various embodiments, processing unit 1004 can execute a variety of programs in response to program code and can maintain multiple concurrently executing programs or processes. At any given time, some or all of the program code to be executed can be resident in processor(s) 1004 and/or in storage subsystem 1018. Through suitable programming, processor(s) 1004 can provide various functionalities described above. Computer system 1000 may additionally include a processing acceleration unit 1006, which can include a digital signal processor (DSP), a special-purpose processor, and/or the like.

I/O subsystem 1008 may include user interface input devices and user interface output devices. User interface input devices may include a keyboard, pointing devices such as a mouse or trackball, a touchpad or touch screen incorporated into a display, a scroll wheel, a click wheel, a dial, a button, a switch, a keypad, audio input devices with voice command recognition systems, microphones, and other types of input devices. User interface input devices may include, for example, motion sensing and/or gesture recognition devices such as the Microsoft Kinect® motion sensor that enables users to control and interact with an input device, such as the Microsoft Xbox® 360 game controller, through a natural user interface using gestures and spoken commands. User interface input devices may also include eye gesture recognition devices such as the Google Glass® blink detector that detects eye activity (e.g., ‘blinking’ while taking pictures and/or making a menu selection) from users and transforms the eye gestures as input into an input device (e.g., Google Glass®). Additionally, user interface input devices may include voice recognition sensing devices that enable users to interact with voice recognition systems (e.g., Siri® navigator), through voice commands.

User interface input devices may also include, without limitation, three dimensional (3D) mice, joysticks or pointing sticks, gamepads and graphic tablets, and audio/visual devices such as speakers, digital cameras, digital camcorders, portable media players, webcams, image scanners, fingerprint scanners, barcode reader 3D scanners, 3D printers, laser rangefinders, and eye gaze tracking devices. Additionally, user interface input devices may include, for example, medical imaging input devices such as computed tomography, magnetic resonance imaging, position emission tomography, medical ultrasonography devices. User interface input devices may also include, for example, audio input devices such as MIDI keyboards, digital musical instruments and the like.

User interface output devices may include a display subsystem, indicator lights, or non-visual displays such as audio output devices, etc. The display subsystem may be a cathode ray tube (CRT), a flat-panel device, such as that using a liquid crystal display (LCD) or plasma display, a projection device, a touch screen, and the like. In general, use of the term “output device” is intended to include all possible types of devices and mechanisms for outputting information from computer system 1000 to a user or other computer. For example, user interface output devices may include, without limitation, a variety of display devices that visually convey text, graphics and audio/video information such as monitors, printers, speakers, headphones, automotive navigation systems, plotters, voice output devices, and modems.

Computer system 1000 may comprise a storage subsystem 1018 that comprises software elements, shown as being currently located within a system memory 1010. System memory 1010 may store program instructions that are loadable and executable on processing unit 1004, as well as data generated during the execution of these programs.

Depending on the configuration and type of computer system 1000, system memory 1010 may be volatile (such as random access memory (RAM)) and/or non-volatile (such as read-only memory (ROM), flash memory, etc.) The RAM typically contains data and/or program modules that are immediately accessible to and/or presently being operated and executed by processing unit 1004. In some implementations, system memory 1010 may include multiple different types of memory, such as static random access memory (SRAM) or dynamic random access memory (DRAM). In some implementations, a basic input/output system (BIOS), containing the basic routines that help to transfer information between elements within computer system 1000, such as during start-up, may typically be stored in the ROM. By way of example, and not limitation, system memory 1010 also illustrates application programs 1012, which may include client applications, Web browsers, mid-tier applications, relational database management systems (RDBMS), etc., program data 1014, and an operating system 1016. By way of example, operating system 1016 may include various versions of Microsoft Windows®, Apple Macintosh®, and/or Linux operating systems, a variety of commercially-available UNIX® or UNIX-like operating systems (including without limitation the variety of GNU/Linux operating systems, the Google Chrome® OS, and the like) and/or mobile operating systems such as iOS, Windows® Phone, Android® OS, BlackBerry® 10 OS, and Palm® OS operating systems.

Storage subsystem 1018 may also provide a tangible computer-readable storage medium for storing the basic programming and data constructs that provide the functionality of some embodiments. Software (programs, code modules, instructions) that when executed by a processor provide the functionality described above may be stored in storage subsystem 1018. These software modules or instructions may be executed by processing unit 1004. Storage subsystem 1018 may also provide a repository for storing data used in accordance with some embodiments.

Storage subsystem 1000 may also include a computer-readable storage media reader 1020 that can further be connected to computer-readable storage media 1022. Together and, optionally, in combination with system memory 1010, computer-readable storage media 1022 may comprehensively represent remote, local, fixed, and/or removable storage devices plus storage media for temporarily and/or more permanently containing, storing, transmitting, and retrieving computer-readable information.

Computer-readable storage media 1022 containing code, or portions of code, can also include any appropriate media, including storage media and communication media, such as but not limited to, volatile and non-volatile, removable and non-removable media implemented in any method or technology for storage and/or transmission of information. This can include tangible computer-readable storage media such as RAM, ROM, electronically erasable programmable ROM (EEPROM), flash memory or other memory technology, CD-ROM, digital versatile disk (DVD), or other optical storage, magnetic cassettes, magnetic tape, magnetic disk storage or other magnetic storage devices, or other tangible computer readable media. This can also include nontangible computer-readable media, such as data signals, data transmissions, or any other medium which can be used to transmit the desired information and which can be accessed by computing system 1000.

By way of example, computer-readable storage media 1022 may include a hard disk drive that reads from or writes to non-removable, nonvolatile magnetic media, a magnetic disk drive that reads from or writes to a removable, nonvolatile magnetic disk, and an optical disk drive that reads from or writes to a removable, nonvolatile optical disk such as a CD ROM, DVD, and Blu-Ray® disk, or other optical media. Computer-readable storage media 1022 may include, but is not limited to, Zip® drives, flash memory cards, universal serial bus (USB) flash drives, secure digital (SD) cards, DVD disks, digital video tape, and the like. Computer-readable storage media 1022 may also include, solid-state drives (SSD) based on non-volatile memory such as flash-memory based SSDs, enterprise flash drives, solid state ROM, and the like, SSDs based on volatile memory such as solid state RAM, dynamic RAM, static RAM, DRAM-based SSDs, magnetoresistive RAM (MRAM) SSDs, and hybrid SSDs that use a combination of DRAM and flash memory based SSDs. The disk drives and their associated computer-readable media may provide non-volatile storage of computer-readable instructions, data structures, program modules, and other data for computer system 1000.

Communications subsystem 1024 provides an interface to other computer systems and networks. Communications subsystem 1024 serves as an interface for receiving data from and transmitting data to other systems from computer system 1000. For example, communications subsystem 1024 may enable computer system 1000 to connect to one or more devices via the Internet. In some embodiments communications subsystem 1024 can include radio frequency (RF) transceiver components for accessing wireless voice and/or data networks (e.g., using cellular telephone technology, advanced data network technology, such as 3G, 4G or EDGE (enhanced data rates for global evolution)), WiFi (IEEE 802.11 family standards, or other mobile communication technologies, or any combination thereof), global positioning system (GPS) receiver components, and/or other components. In some embodiments communications subsystem 1024 can provide wired network connectivity (e.g., Ethernet) in addition to or instead of a wireless interface.

In some embodiments, communications subsystem 1024 may also receive input communication in the form of structured and/or unstructured data feeds 1026, event streams 1028, event updates 1030, and the like on behalf of one or more users who may use computer system 1000.

By way of example, communications subsystem 1024 may be configured to receive data feeds 1026 in real-time from users of social networks and/or other communication services such as Twitter® feeds, Facebook® updates, web feeds such as Rich Site Summary (RSS) feeds, and/or real-time updates from one or more third party information sources.

Additionally, communications subsystem 1024 may also be configured to receive data in the form of continuous data streams, which may include event streams 1028 of real-time events and/or event updates 1030, that may be continuous or unbounded in nature with no explicit end. Examples of applications that generate continuous data may include, for example, sensor data applications, financial tickers, network performance measuring tools (e.g. network monitoring and traffic management applications), clickstream analysis tools, automobile traffic monitoring, and the like.

Communications subsystem 1024 may also be configured to output the structured and/or unstructured data feeds 1026, event streams 1028, event updates 1030, and the like to one or more databases that may be in communication with one or more streaming data source computers coupled to computer system 1000.

Computer system 1000 can be one of various types, including a handheld portable device (e.g., an iPhone® cellular phone, an iPad® computing tablet, a PDA), a wearable device (e.g., a Google Glass® head mounted display), a PC, a workstation, a mainframe, a kiosk, a server rack, or any other data processing system.

Due to the ever-changing nature of computers and networks, the description of computer system 1000 depicted in the figure is intended only as a specific example. Many other configurations having more or fewer components than the system depicted in the figure are possible. For example, customized hardware might also be used and/or particular elements might be implemented in hardware, firmware, software (including applets), or a combination. Further, connection to other computing devices, such as network input/output devices, may be employed. Based on the disclosure and teachings provided herein, other ways and/or methods to implement the various embodiments should be apparent.

In the foregoing description, for the purposes of explanation, numerous specific details were set forth in order to provide a thorough understanding of various embodiments. It will be apparent, however, that some embodiments may be practiced without some of these specific details. In other instances, well-known structures and devices are shown in block diagram form.

The foregoing description provides exemplary embodiments only, and is not intended to limit the scope, applicability, or configuration of the disclosure. Rather, the foregoing description of various embodiments will provide an enabling disclosure for implementing at least one embodiment. It should be understood that various changes may be made in the function and arrangement of elements without departing from the spirit and scope of some embodiments as set forth in the appended claims.

Specific details are given in the foregoing description to provide a thorough understanding of the embodiments. However, it will be understood that the embodiments may be practiced without these specific details. For example, circuits, systems, networks, processes, and other components may have been shown as components in block diagram form in order not to obscure the embodiments in unnecessary detail. In other instances, well-known circuits, processes, algorithms, structures, and techniques may have been shown without unnecessary detail in order to avoid obscuring the embodiments.

Also, it is noted that individual embodiments may have beeen described as a process which is depicted as a flowchart, a flow diagram, a data flow diagram, a structure diagram, or a block diagram. Although a flowchart may have described the operations as a sequential process, many of the operations can be performed in parallel or concurrently. In addition, the order of the operations may be re-arranged. A process is terminated when its operations are completed, but could have additional steps not included in a figure. A process may correspond to a method, a function, a procedure, a subroutine, a subprogram, etc. When a process corresponds to a function, its termination can correspond to a return of the function to the calling function or the main function.

The term “computer-readable medium” includes, but is not limited to portable or fixed storage devices, optical storage devices, wireless channels and various other mediums capable of storing, containing, or carrying instruction(s) and/or data. A code segment or machine-executable instructions may represent a procedure, a function, a subprogram, a program, a routine, a subroutine, a module, a software package, a class, or any combination of instructions, data structures, or program statements. A code segment may be coupled to another code segment or a hardware circuit by passing and/or receiving information, data, arguments, parameters, or memory contents. Information, arguments, parameters, data, etc., may be passed, forwarded, or transmitted via any suitable means including memory sharing, message passing, token passing, network transmission, etc.

Furthermore, embodiments may be implemented by hardware, software, firmware, middleware, microcode, hardware description languages, or any combination thereof. When implemented in software, firmware, middleware or microcode, the program code or code segments to perform the necessary tasks may be stored in a machine readable medium. A processor(s) may perform the necessary tasks.

In the foregoing specification, features are described with reference to specific embodiments thereof, but it should be recognized that not all embodiments are limited thereto. Various features and aspects of some embodiments may be used individually or jointly. Further, embodiments can be utilized in any number of environments and applications beyond those described herein without departing from the broader spirit and scope of the specification. The specification and drawings are, accordingly, to be regarded as illustrative rather than restrictive.

Additionally, for the purposes of illustration, methods were described in a particular order. It should be appreciated that in alternate embodiments, the methods may be performed in a different order than that described. It should also be appreciated that the methods described above may be performed by hardware components or may be embodied in sequences of machine-executable instructions, which may be used to cause a machine, such as a general-purpose or special-purpose processor or logic circuits programmed with the instructions to perform the methods. These machine-executable instructions may be stored on one or more machine readable mediums, such as CD-ROMs or other type of optical disks, floppy diskettes, ROMs, RAMs, EPROMs, EEPROMs, magnetic or optical cards, flash memory, or other types of machine-readable mediums suitable for storing electronic instructions. Alternatively, the methods may be performed by a combination of hardware and software.

In the preceding description, for the purposes of explanation, numerous details have been set forth in order to provide an understanding of various embodiments of the present technology. It will be apparent to one skilled in the art, however, that certain embodiments may be practiced without some of these details, or with additional details.

Having disclosed several embodiments, it will be recognized by those of skill in the art that various modifications, alternative constructions, and equivalents may be used without departing from the spirit of the embodiments. Additionally, a number of well-known processes and elements have not been described in order to avoid unnecessarily obscuring the present technology. Accordingly, the above description should not be taken as limiting the scope of the technology.

Where a range of values is provided, it is understood that each intervening value, to the smallest fraction of the unit of the lower limit, unless the context clearly dictates otherwise, between the upper and lower limits of that range is also specifically disclosed. Any narrower range between any stated values or unstated intervening values in a stated range and any other stated or intervening value in that stated range is encompassed. The upper and lower limits of those smaller ranges may independently be included or excluded in the range, and each range where either, neither, or both limits are included in the smaller ranges is also encompassed within the technology, subject to any specifically excluded limit in the stated range. Where the stated range includes one or both of the limits, ranges excluding either or both of those included limits are also included.

As used herein and in the appended claims, the singular forms “a”, “an”, and “the” include plural references unless the context clearly dictates otherwise. Thus, for example, reference to “a flexure” includes a plurality of such flexures, and reference to “the protrusion” includes reference to one or more protrusions and equivalents thereof known to those skilled in the art, and so forth.

Also, the words “comprise(s)”, “comprising”, “contain(s)”, “containing”, “include(s)”, and “including”, when used in this specification and in the following claims, are intended to specify the presence of stated features, integers, components, or operations, but they do not preclude the presence or addition of one or more other features, integers, components, operations, acts, or groups.

What is claimed is:

1. A semiconductor processing system, comprising:
a substrate support defining an aperture therethrough;
a light assembly comprising a light source that emits an optical signal that is directed toward the aperture, the optical signal having a high angle of incidence relative to the substrate support; and
a photodetector aligned with an angle of reflectance of the optical signal.

2. The semiconductor processing system of claim 1, further comprising:
a high refractive index fluid positioned within the aperture, wherein the high refractive index fluid has a refractive index that is sufficiently high that a magnitude of a tangential wave vector of the optical signal is greater than a magnitude of a wavenumber of a top film of a substrate being processed.

3. The semiconductor processing system of claim 1, further comprising:
a platen positioned below the substrate support, the platen defining a channel that optically couples the light assembly, the aperture, and the photodetector, wherein:
a first end of the channel is sealed by a first quartz window positioned between the first end of the channel and the light assembly; and
a second end of the channel is sealed by a second quartz window positioned between the second end of the channel and the photodetector.

4. The semiconductor processing system of claim 1, wherein:
the light assembly comprises a collimated light source.

5. The semiconductor processing system of claim 1, wherein:
the light assembly comprises at least one mirror that directs light from a light source to the aperture.

6. The semiconductor processing system of claim 1, further comprising a controller, wherein the controller comprises:
one or more processors; and
one or more memory devices storing instructions that, when executed by the one or more processors, cause the one or more processors to perform operations comprising:
receiving an amount of the optical signal that is received by the photodetector; and
determining a thickness of an outermost layer of film on a substrate based at least in part on the amount of the optical signal that is received by the photodetector.

7. The semiconductor processing system of claim 6, wherein the controller comprises a model that is trained to receive the amount of the optical signal that is received by the photodetector and output an indication of the thickness of an outermost layer of the film on the substrate.

8. The semiconductor processing system of claim 7, wherein the model comprises a neural network that is trained to classify a location on the substrate as having the outermost layer of the film removed, having a thin layer of the film, or having a thick layer of the film.

9. The semiconductor processing system of claim 7, wherein the operations further comprise controlling a polishing process performed on the substrate using the indication of the thickness of the outermost layer of the film on the substrate output by the model.

10. The semiconductor processing system of claim 7, wherein the model receives the amount of the optical signal that is received by the photodetector as a real-time stream of measurement data received during a polishing process performed on the substrate.

11. A method of determining thicknesses of films of on semiconductor substrates, the method comprising:
directing an optical signal to a semiconductor substrate that is positioned on a substrate support;
receiving a reflected portion of the optical signal from the semiconductor substrate using a photodetector;
determining an amount of the optical signal that was received by the photodetector in the form of the reflected portion; and
determining a thickness of an outermost layer of film of the semiconductor substrate based at least in part on the amount of the optical signal that was received by the photodetector in the form of the reflected portion.

12. The method of claim 11, wherein:
a lower magnitude of the reflected portion corresponds with the outermost layer of film having a lower thickness.

13. The method of claim 11, further comprising:
moving the semiconductor substrate relative to the substrate support; and
determining a film thickness at an additional portion of the semiconductor substrate.

14. The method of claim 11, further comprising:
providing a high refractive index fluid on the outermost layer of film of the semiconductor substrate by pumping the high refractive index fluid onto the outermost layer of film.

15. The method claim 11, further comprising:
polishing the semiconductor substrate; and
stopping the polishing upon determining that the thickness of an outermost layer of film of the semiconductor substrate has reached a predetermined threshold.

16. The method of claim 11, wherein determining the thickness of the outermost layer of film of the semiconductor substrate comprises:
providing the amount of the optical signal that was received by the photodetector in the form of the reflected portion to a model trained to classify the thickness of substrate films; and
receiving an output from the model comprising an indication of the thickness of the outermost layer of the film on the substrate.

17. A method of determining a thickness of a film of a semiconductor substrate, comprising:
directing an optical signal to a semiconductor substrate that is positioned on a substrate support;
receiving a reflected portion of the optical signal from the semiconductor substrate using a photodetector;
providing an input based on the reflected portion of the optical signal to a model that is trained to classify a thickness of an outermost layer of film on the semiconductor substrate; and
determining a thickness of the outermost layer of film of the semiconductor substrate based at least in part on an output from the model.

18. The method of claim 17, wherein the model comprises a neural network that is trained to classify a location on the semiconductor substrate as having the outermost layer of the film removed, having a thin layer of the film, or having a thick layer of the film.

19. The method of claim 17, further comprising controlling a polishing process performed on the substrate using the thickness of the outermost layer of the film on the substrate output by the model.

20. The method of claim 17, wherein the model receives the reflected portion of the optical signal as a real-time stream of measurement data received during a polishing process performed on the substrate.
